(19) United States
(12) Patent Application Publication
(10) Pub. No.: US 2012/0086096 A1
(43) Pub. Date: Apr. 12, 2012

(54) CONDENSER LENS-COUPLED PHOTOCONDUCTIVE ANTENNA DEVICE FOR TERAHERTZ WAVE GENERATION AND DETECTION AND FABRICATING METHOD THEREOF

(75) Inventors: Mun Cheol Paek, Daejeon (KR); Kwang-Yong Kang, Daejeon (KR); Min Hwan Kwak, Daejeon (KR); Seungbeom Kang, Chungcheongbuk-do (KR)

(73) Assignee: ELECTRONICS AND TELECOMMUNICATIONS RESEARCH INSTITUTE, Daejeon (KR)

(21) Appl. No.: 13/268,147

(22) Filed: Oct. 7, 2011

(30) Foreign Application Priority Data
Oct. 8, 2010 (KR) 10-2010-0098262
Sep. 27, 2011 (KR) 10-2011-0097510

(51) Int. Cl. H01L 31/0232; H01L 31/18

(52) U.S. Cl. 257/432; 438/69; 257/E31.127

(57) ABSTRACT

Provided are a condenser lens-coupled photoconductive antenna device for terahertz wave generation and detection and a fabricating method thereof. A condenser lens-coupled photoconductive antenna device for terahertz wave generation and detection includes a condenser lens, a photoconductive thin film deposited on the condenser lens, and a metal electrode formed on the photoconductive thin film for a photoconductive antenna. In the antenna device, the condenser lens and the photoconductive thin film are coupled to each other.

### CROSS-REFERENCES TO RELATED APPLICATIONS

The present application claims priority under 35 U.S.C 119(a) to Korean Application No. 10-2010-0098262, filed on Oct. 8, 2010, and Korean Application No. 10-2011-0097510, filed on Sep. 27, 2011, in the Korean Intellectual Property Office, which is incorporated herein by reference in its entirety set forth in full.

### BACKGROUND

Exemplary embodiments of the present invention relate to a condenser lens-coupled photoconductive antenna device for terahertz wave generation and detection and a fabricating method thereof.

The background art has been disclosed in Korean Patent No. 0645800 (published on Nov. 14, 2006).

Terahertz waves are electromagnetic waves corresponding to a frequency band between 0.1 and 10 THz. The terahertz waves lie between radio and light waves, and have wavelengths shorter than those of millimeter waves and longer than those of infrared waves.

Accordingly, since the terahertz waves have particular characteristics different from other electromagnetic waves, studies on the terahertz waves have been conducted in various science fields, and the terahertz waves will be applied to various industrial fields in the near future. However, terahertz wave generation and detection techniques have recently developed, and most of the techniques require high-cost equipment and up-to-date electronic and photonic technology. Among these techniques, a technique using a photoconductive antenna device based on an LT-GaAs thin film has been successfully developed and commercialized. As low-cost, small and light products have recently been introduced, the expectation of marketability is increased.

FIG. 1 illustrates sequential fabrication processes a conventional photoconductive antenna device. The fabrication processes of the conventional photoconductive antenna device will be described with reference to FIG. 1.

First, a semi-insulating GaAs substrate 101 of about 2 inches diameter is prepared for deposition, and an LT-GaAs thin film 102 is deposited on the GaAs substrate 101 by a deposition apparatus such as molecular beam epitaxy (MBE) or the like. In this case, it is important to prevent a crystal defect by control processing temperature and time and heat-treating temperature and time. After the deposition of the thin film 102 is completed, metal electrodes 103 for a photoconductive antenna pattern are formed on a surface of the deposited thin film 102. Aluminum, gold or the like is used as a material of the electrode 103, and an alloy containing two or more metals may be used as the material of the electrode 103 as occasion demands.

If the formation of electrode patterns is completed, the 2 inch substrate 101 is cut into individual chip with antenna patter, and a condenser lens 104 is then adhered to a rear surface of each of the substrates. In this case, it is important to exactly align centers of the metal pattern and the condenser lens. It is also important to allow the substrate and the lens to be adhered closely to each other so that void is not formed between the substrate and the lens. This is because when an extremely small amount of void exists between the substrate and the lens, scattering of terahertz waves occurs, and then noise is generated. Therefore, the entire performance of a system is lowered, and the quality of spectrum and image obtained is deteriorated.

However, when the photoconductive material is attached to the condenser lens as described above, it is very difficult to exactly align the centers of the electrode pattern and the condenser lens and to allow the substrate and the silicon lens to be adhered closely to each other so that a void is not formed between the substrate and the silicon lens. In a case where the aforementioned operation is not smoothly performed, the scattering of terahertz waves occurs due to void, and therefore, noise may be caused in a terahertz signal. Since the semi-insulating GaAs substrate made of a semiconductor material has a low penetration rate with respect to the terahertz waves as compared with high-resistance silicon, the signal to noise ratio (SNR) of the terahertz signal is degraded.

### SUMMARY

An embodiment of the present invention relates to a condenser lens-coupled photoconductive antenna device for terahertz wave generation and detection and a fabricating method thereof, which can solve problems on an LT-GaAs-based photoconductive antenna device which widely used in the conventional photoconductive antenna and partially commercialized.

In one embodiment, a condenser lens-coupled photoconductive antenna device for terahertz wave generation and detection includes a condenser lens, a photoconductive thin film deposited on the condenser lens, and a metal electrode for a photoconductive antenna, formed on the photoconductive thin film. In the antenna device, the condenser lens and the photoconductive thin film are coupled to each other.

In another embodiment, a fabricating method of a condenser lens-coupled photoconductive antenna device for terahertz wave generation and detection includes forming a condenser lens, depositing a photoconductive thin film on the condenser lens, and forming a metal electrode for a photoconductive antenna on the photoconductive thin film. In the method, the condenser lens and the photoconductive thin film are coupled to each other.

The condenser lens may be formed in a super-hemispheric shape and made of high-resistive silicon.

The photoconductive thin film may be made of polycrystalline GaAs.

The depositing of the photoconductive thin film on the condenser lens may be performed in the state that the condenser lens is mounted in a sample holder for accommodating the condenser lens.

The sample holder may include a mounting portion having an insertion portion in which the super-hemispherical condenser lens is mounted, and a cover portion having a through-hole into which the super-hemispherical condenser lens is inserted.

The insertion portion of the mounting portion may be a hemispherical concave portion, and the radius of the through-hole may be decreased as the through-hole approaches from the bottom to the top thereof.

### BRIEF DESCRIPTION OF THE DRAWINGS

The above and other aspects, features and other advantages will be more clearly understood from the following detailed description taken in conjunction with the accompanying drawings, in which:

FIG. 1 illustrates a sequential fabrication processes of a conventional photoconductive antenna device;

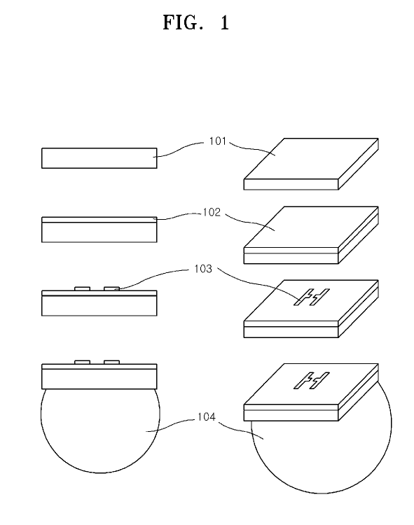

FIG. 2 is a conceptual view illustrating a configuration of a photoconductive antenna device for terahertz wave generation according to an embodiment of the present invention;

FIG. 3 illustrates a sequential fabrication processes of the conventional photoconductive antenna device according to the embodiment of the present invention; and

FIG. 4 illustrates a structure of a designed sample holder used according to the embodiment of the present invention.

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

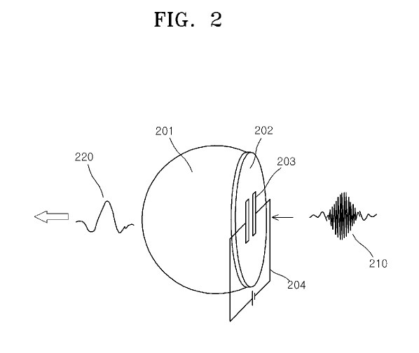

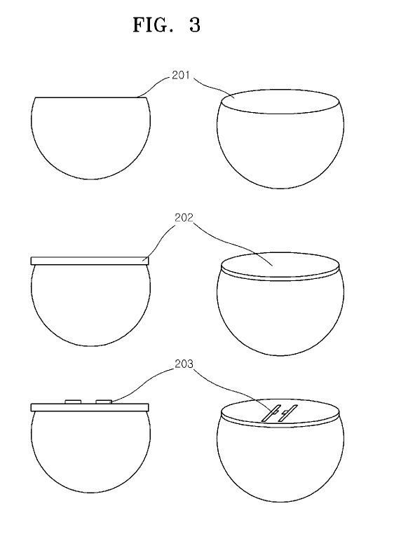

FIG. 2 is a conceptual view illustrating a configuration of a photoconductive antenna device for terahertz wave generation according to an embodiment of the present invention. FIG. 3 illustrates a sequential fabrication processes of the conventional photoconductive antenna device according to the embodiment of the present invention. The embodiment of the present invention will be described with reference to FIGS. 2 and 3.

As illustrated in FIGS. 2 and 3, the condenser lens-coupled photoconductive antenna device according to this embodiment includes a condenser lens 201, a photoconductive thin film 202 deposited on the condenser lens 201, and metal electrodes 203 for a photoconductive antenna formed on the photoconductive thin film 202. The condenser lens 201 and the photoconductive thin film 202 are coupled to each other.

The condenser lens 201 is formed in a super-hemispherical shape and made of high-resistive silicon. The photoconductive thin film 202 is made of polycrystalline GaAs.

The operation of this embodiment configured as described above will be described in detail with reference to FIGS. 2 to 4.

Photoconductive antenna devices are still fabricated at a very high cost due to technical difficulty and material price. Many studies for solving such a problem have been carried out. Among these studies, a research using a polycrystalline GaAs thin film has been conducted into patents, and various applications using the research can be developed.
Korean Patent Application: 2009-0118339
U.S. patent application Ser. No. 12/787,841
Japanese Patent Application: 2010-139599

Details for properties of the terahertz waves, a principle of the photoconductive antenna and characteristics of the polycrystalline GaAs thin film can refer to the patent applications. As disclosed in the patent applications, the polycrystalline thin film can be grown regardless of the kind of substrate, and hence there is no condition that a GaAs single-crystalline substrate is necessarily used to grow the conventional LT-GaAs thin film. Therefore, the polycrystalline thin film can be grown on silicon, quartz, sapphire and glass, and then its possibility has already been verified. Thus, it is possible to deposit a photoconductive thin film directly on high-resistive silicon used as a material for the condenser lens without a substrate. Particularly, the high-resistive silicon is a material having a very high penetration rate with respect to the terahertz waves. The high-resistance can minimize absorption of the terahertz waves onto the conventional semi-insulating GaAs substrate, thereby obtaining strong terahertz wave signals.

FIG. 2 illustrates a configuration of the photoconductive antenna device fabricated according to this embodiment and a principle of terahertz wave generation.

Referring to FIG. 2, the photoconductive antenna device according to this embodiment includes the metal electrodes 203 for the photoconductive antenna, the photoconductive thin film 202 and the condenser lens 201. A femtosecond laser pulse 210 having a pulse duration of 10 to 100 fs is necessary to generate a terahertz wave. The condenser lens 201 with a super-hemispheric shape, made from high-resistive silicon that is a material having a high penetration rate with respect to the terahertz wave and having a high refractive index, is generally used to condense the generated terahertz wave in a certain direction. Here, the super-hemispheric shape means a shape identical to that of the condenser lens 201 illustrated in FIGS. 2 and 3. The super-hemispheric shape means a shape further extended upward to approach a spherical shape from a hemispherical shape.

The principle of terahertz wave generation will be described with reference to FIG. 2. If the femtosecond laser pulse 210 is incident between the electrodes 203 to which a DC bias voltage from 10 to 50V is applied, electron-hole pairs are generated in the photoconductive thin film 202, and the generated electric charges are moved to both the electrodes by the bias voltage, thereby generating photocurrent. The photocurrent is flowed by a microwave pulse for a short time, and an electromagnetic field is formed by a change in photocurrent. When the moving time of photoelectric charges is short as a pico-second or so, a terahertz wave 220 is generated by the electromagnetic field. The generation and detection of the terahertz wave 220 is made to the entire space. Since the dielectric constant of the photoconductive thin film 202 and the condenser lens 201 is much greater than that in a free space, most of the terahertz waves are emitted in the direction of the thin film. Therefore, the silicon condenser lens 201 is used to condense the terahertz waves in one direction.

An antenna device for terahertz wave detection according to this embodiment has the same structure and material as the antenna device for terahertz wave generation. However, in the antenna device for terahertz wave detection, the shape of an antenna electrode for detection may be changed to improve detection characteristics.

FIG. 3 illustrates a fabricating method of the photoconductive antenna device according to this embodiment. Here, it is unnecessary to prepare a semi-insulating GaAs substrate formed from the conventional process, and a photoconductive thin film 202 is deposited directly on a flat surface of a silicon condenser lens 201. Since the photoconductive thin film 202 is made of polycrystalline GaAs, MBE system is not necessarily for deposition of thin films and various methods such as organic metal chemical vapor deposition (MOCVD) or sputtering may be applied to the deposition system.

If the deposition of the photoconductive thin film 202 is completed, metal electrodes 203 for a photoconductive antenna are formed. Since the metal electrode 203 is directly formed on the photoconductive thin film 202 deposited on the silicon condenser lens 201, the process is performed while aligning centers of the metal electrodes 203 and the photoconductive thin film 202, without attaching the metal electrode 203 to the photoconductive thin film 202 through a separate alignment process. Accordingly, the number of substrates used can be decreased as compared with the conventional method. As processes are simplified, time and cost can be saved. Further, the misalignment between the metal electrodes 203 and the silicon condenser lens 201 can be reduced, thereby obtain improvable effects.

That is, according to this embodiment, the polycrystalline GaAs thin film is directly deposited on the silicon condenser lens, so that it is possible to considerably simplify the whole fabricating processes and prevent an error generation, thereby saving time and lowering cost. Further, it is possible to improve the performance and reliability of the photoconductive antenna device by simplifying processes and solving an alignment problem. This becomes a basis for mass production when terahertz systems are commercialized in the long term.

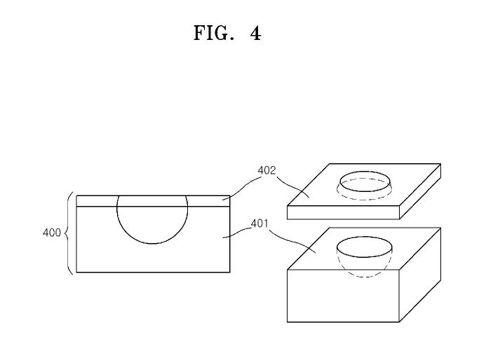

FIG. 4 illustrates a separated sample holder 400 necessary for performing direct deposition on a flat surface of the silicon condenser lens related the process of FIG. 3. The sample holder 400 includes a mounting portion 401 having an insertion portion in which the super-hemispherical condenser lens 201 is mounted, and a cover portion 402 having a through-hole into which the super-hemispherical condenser lens 201 is inserted. The insertion portion of the mounting portion 401 is a hemispherical concave portion, and the radius of the through-hole is decreased as the through-hole approaches from the bottom to the top thereof.

Since a thin film is basically deposited on a wafer in a general semiconductor deposition system, the sample holder 400 according to this embodiment is separately required to load a condenser lens having a certain volume into the semiconductor deposition system. Since the silicon condenser lens 210 has a super-hemispherical shape, the sample holder 400 is divided into two components in this embodiment. If the condenser lens 201 is first mounted in the hemispherical mounting portion 401 and the top of the mounting portion 401 is covered with the cover portion 402, the condenser lens 201 is not come from the sample holder 400 even though the entire sample holder 400 is turned over. This is because the radius of the through-hole is decreased as the through-hole approaches from the bottom to the top thereof. In some semiconductor deposition systems, the upper and lower portions of a sample may be turned over while being mounted in a sample holder, which can be prevented by the sample holder 400 according to this embodiment. The size of the sample holder 400 may be formed suitable for the size of the condenser lens 201 to be used, and the diameter of the sample holder 400 is generally from 10 to 12 mm.

According to the present invention, a polycrystalline GaAs thin film is directly deposited on a silicon condenser lens, so that it is possible to considerably simplify fabrication processes and prevent an error generation, thereby saving time and lowering cost. Further, it is possible to improve the performance and reliability of the photoconductive antenna device by simplifying processes and solving an alignment problem. This becomes a basis for mass production when terahertz systems are commercialized in the long term.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A condenser lens-coupled photoconductive antenna device for terahertz wave generation and detection, the antenna device comprising:
a condenser lens;
a photoconductive thin film deposited on the condenser lens; and
a metal electrode for a photoconductive antenna, formed on the photoconductive thin film,
wherein the condenser lens and the photoconductive thin film are coupled to each other.

2. The antenna device of claim 1, wherein the condenser lens is formed in a super-hemispherical shape and made from high-resistive silicon.

3. The antenna device of claim 1, wherein the photoconductive thin film is made of polycrystalline GaAs.

4. The antenna device of claim 1, wherein the condenser lens is formed in a super-hemispherical shape and made from high-resistive silicon, and the photoconductive thin film is made of polycrystalline GaAs.

5. A fabricating method of a condenser lens-coupled photoconductive antenna device for terahertz wave generation and detection, the method comprising:
forming a condenser lens;
depositing a photoconductive thin film on the condenser lens; and
forming a metal electrode for a photoconductive antenna on the photoconductive thin film,
wherein the condenser lens and the photoconductive thin film are coupled to each other.

6. The method of claim 5, wherein the condenser lens is formed in a super-hemispherical shape and made from high-resistance silicon.

7. The method of claim 5, wherein the photoconductive thin film is made of polycrystalline GaAs.

8. The method of claim 5, wherein the condenser lens is formed in a super-hemispherical shape and made from high-resistive silicon, and the photoconductive thin film is made of polycrystalline GaAs.

9. The method of claim 6, wherein the depositing of the photoconductive thin film on the condenser lens is performed in the state that the condenser lens is mounted in a sample holder for accommodating the condenser lens.

10. The method of claim 9, wherein the sample holder comprises:
a mounting portion having an insertion portion in which the super-hemispherical condenser lens is mounted; and
a cover portion having a through-hole into which the super-hemispherical condenser lens is inserted.

11. The method of claim 10, wherein the insertion portion of the mounting portion is a hemispherical concave portion, and the radius of the through-hole is decreased as the through-hole approaches from the bottom to the top thereof.
